(19) United States
(12) Patent Application Publication
(10) Pub. No.: US 2014/0008604 A1
(43) Pub. Date: Jan. 9, 2014

(54) Super-Long Semiconductor Nano-Wire Structure and Method of Making

(71) Applicants: Dongping Wu, Shanghai (CN); Shi-Li Zhang, Stockholm (SE); Zhiwei Zhu, Shanghai (CN); Wei Zhang, Shanghai (CN)

(72) Inventors: Dongping Wu, Shanghai (CN); Shi-Li Zhang, Stockholm (SE); Zhiwei Zhu, Shanghai (CN); Wei Zhang, Shanghai (CN)

(73) Assignee: FUDAN UNIVERSITY, Shanghai (CN)

(21) Appl. No.: 13/502,110

(22) PCT Filed: Sep. 28, 2011
(86) PCT No.: PCT/CN11/80273

§ 371 Date: Apr. 13, 2012

(30) Foreign Application Priority Data
Mar. 17, 2011 (CN) 201110064599.1

(51) Int. Cl. H01L 29/06; H01L 21/308

(52) U.S. Cl. CPC H01L 29/0669; H01L 21/3083
USPC 257/9; 438/694

(57) ABSTRACT

The present invention disclosure provides a super-long semiconductor nanowire structure. The super-long semiconductor nanowire structure is intermittently widened to prevent fractures in the super-long semiconductor nanowire structure. At the same time, the present invention further provides a method of making a super-long semiconductor nanowire structure. The method forms an intermittently widened super-long semiconductor nanowire structure using photolithography and etching. Because the super-long semiconductor nanowire structure is intermittently widened, fracturing of the super-long semiconductor nanowire structure during etching can be avoided, making it easier to form a super-long and ultra-thin semiconductor nanowire structure.

### FIELD

The present invention is related to semiconductor processing technologies, and more particularly to a super-long semiconductor nanowire structure and method of making.

### BACKGROUND

Currently, advanced semiconductor integrated circuit processing has entered nanometer range, and feature sizes of transistors continue to shrink proportionately. While device performance is being enhanced and cost for individual transistors is being lowered, higher demand is being placed on semiconductor processing technologies. This, together with quantum mechanical effects, means that the feature sizes of devices cannot shrink indefinitely. Conventional semiconductor materials and processes will meet their bottlenecks, and semiconductor industries will stop following the Moore's law. Therefore, a pressing need exists to develop new materials and new processes to replace conventional integrated circuit materials and processes. One-dimensional materials such as nanowires, nanotubes, and the like, as necessary functional components in nano-scale electronic devices, have thus become more and more important in the field of nano-scale research.

In addition, much interest has been shown in the research of low-dimension, small-scale materials in the recent decades and in the field of condensed matter physics. Nowadays, nano structures are tremendously challenging areas of research in the forefront of scientific and technological development. Especially during the recent years, nano-scale silicon wires are drawing more and more attentions, on one hand because of their potential application prospects, such as device miniaturization, enhancement in the degree of integration, and their use in making various special devices, etc., and on the other hand because of the special physical properties manifested by small-scale silicon materials, such as surface effect, mechanical effect, photo-luminescent characteristics, and quantum-size effect, etc. Therefore, nano-scale silicon wires are becoming more and more important in the scientific world.

Currently, silicon nanowires are made mainly using two conventional methods for making nano materials: “top-down” method and “bottom-up” method. In the “top-down” method, a large piece of silicon is used to obtain the nano materials by etching, corrosion or abrasion. In the “bottom-up” method, various nano materials and nano structures are produced by controlling and assembling atoms or molecules and bring about reactions among them, typically using chemical vapor deposition (CVD).

Besides the limitations associated with the “bottom-up” method itself (e.g., high temperature, high pressure, etc.), the silicon nanowires made using the method demonstrate certain shortcomings in subsequent processes for making nanowire electronic devices, such as difficulty to position and move, and difficulty to form good ohm contact. On the contrary, the “top-down” method utilizes conventional microelectronics fabrication processes, and can thus be used for mass manufacturing, making it possible to fabricate high density and high quality nano-integrated sensors. Therefore, the “top-down” method is the main technology for making conventional nanowires.

Conventional “top-down” method mainly uses chemical etching to form nanowires. Reference is now made to FIG. 1 and FIGS. 2A to 2E, where FIG. 1 is a flowchart illustrating a conventional “top-down” method for making silicon nanowires, and FIGS. 2A to 2E are structural diagrams of a silicon substrate corresponding to respective steps in the “top-down” method for making the silicon nanowires. As shown in FIG. 1, as well as in FIGS. 2A to 2E, the conventional “top-down” method for making silicon nanowires includes the following steps:
S101—preparing a semiconductor substrate 110, wherein the semiconductor substrate 110 can be silicon on insulator (SOI), which includes an insulator layer 111, a oxidized layer 112 over the insulator layer 111, and a single-crystal silicon layer 113 over the oxidized layer 112, as shown by a cross-sectional diagram of the semiconductor substrate 110 in FIG. 2A;
S102—adding a layer of photoresist 120, and patterning the photoresist 120, as shown by an overview of the semiconductor substrate with the patterned photoresist 120 in FIG. 2B, wherein the photoresist can be patterned using any common photolithography, nano-imprint lithography, electron-beam (e-beam) lithography, or X-ray lithography methods;
S103—dry etching the single-crystal silicon 113 using the patterned photoresist 120 as mask to form primary silicon nanowires 114, as shown by a cross-sectional diagram of the semiconductor substrate after forming the primary nanowires in FIG. 2C, wherein an etchant gas used in the dry etching is HCl.
S104—wet etching the primary silicon nanowires 114 to further reduce the sizes of the primary nanowires 111, forming final nanowires 115, as shown by a cross-sectional diagram of the semiconductor substrate after forming the final silicon nanowires in FIG. 2D, wherein an etchant used in the wet etch can be KOH or hydroxide four methyl amine (TMAH); and
S105—removing the remaining photoresist 120, as shown in a top-view diagram of the semiconductor substrate after removing the photoresist in FIG. 2E.
Obviously, the silicon substrate 110 can also be single-crystal silicon.

Germanium nanowires can be made using similar methods for making silicon nanowires. One only needs to replace the silicon substrate with germanium substrate (either single-crystal germanium or germanium on insulator).

However, because silicon dry etching as well as wet etching in the above method has anisotropic properties, and because silicon nanowires are very narrow (typically a few nanometers to a few tens of nanometers), the silicon nanowires are very easy to fracture during the etching processes, making it difficult to form super-long silicon nanowires. In order to enhance the integration density of processes, silicon nanowires are desired to be as long as possible, so that a single silicon nanowire can have a large number of devices integrated thereon.

Therefore, how to effectively make super-long silicon nanowires or germanium nanowires has become a technological problem much needed to be solved in the industry.

### SUMMARY

The present invention purports to provide a super-long semiconductor nanowire structure and method of making, so as to solve the problems of super-long semiconductor nanowires fracturing during conventional processes of making super-long semiconductor nanowires.

To solve the above problems, the present invention provides a super-long semiconductor nanowire structure, comprising a super-long semiconductor nanowire and flanges. The flanges are symmetrically disposed on two sides of the super-long semiconductor nanowire, thereby widening the super-long semiconductor nanowire. Also, the flanges on either side of the super-long semiconductor nanowire are intermittently disposed with spaces therebetween.

In one embodiment, the flanges are about 2˜100 nm wide.

In one embodiment, the super-long semiconductor nanowire is about 0.5˜500 μm long.

In one embodiment, the super-long semiconductor nanowire is about 2˜200 nm wide.

In one embodiment, the flanges and the super-long semiconductor nanowire are formed together as a one-piece structure.

In one embodiment, the super-long semiconductor nanowire is a super-long silicon nanowire or a super-long germanium nanowire, and the flanges are respectively silicon flanges or germanium flanges.

At the same time, in order to solve the above problems, the present invention further provides a method for making a super-long semiconductor nanowire structure. The method comprises:
providing a semiconductor substrate;
covering the semiconductor substrate with photoresist and patterning the photoresist, the patterned photoresist having an intermittently widened line shape;
etching the semiconductor substrate using the patterned photoresist as a mask to form the super-long semiconductor nanowire structure;
removing the remaining photoresist.

In one embodiment, the photoresist is patterned using any of photolithography, nano-imprint lithography, electron-beam (e-beam) lithography, and X-ray lithography methods.

In one embodiment, the etching is wet etching or dry etching followed by wet etching.

In one embodiment, an etchant used during the wet etching is KOH or hydroxide four methyl amine.

In one embodiment, an etchant gas used during the dry etching includes at least one of CF₄, SiF₆, Cl₂, HBr, and HCl.

In one embodiment, the method further comprises oxidizing the semiconductor substrate before the wet etching.

In one embodiment, the flanges are about 2˜100 nm wide.

In one embodiment, the super-long semiconductor nanowire is about 0.5˜500 μm long.

In one embodiment, the super-long semiconductor nanowire is about 2˜200 nm wide.

In one embodiment, the flanges and the super-long semiconductor nanowire are formed together as a one-piece structure.

In one embodiment, the semiconductor substrate is single-crystal silicon or silicon on insulator, the super-long semiconductor nanowire is a super-long silicon nanowire, and the flanges are silicon flanges.

In one embodiment, the semiconductor substrate is single-crystal germanium or germanium on insulator, the super-long semiconductor nanowire is a super-long germanium nanowire, and the flanges are germanium flanges.

Compared with conventional technologies, the super-long semiconductor nanowire structure provided by the present invention has flanges disposed on two sides of a common super-long semiconductor nanowire, thereby widening the super-long semiconductor nanowire. The flanges on either side of the super-long semiconductor nanowire are intermittently disposed, thereby preventing the super-long semiconductor nanowire structure from fracturing.

Compared with conventional technologies, the method of making a super-long semiconductor nanowire structure provided by the present invention uses photolithography and etching to form an intermittently widened super-long semiconductor nanowire structure. Because the super-long semiconductor nanowire structure is intermittently widened, fracturing of the super-long semiconductor nanowire structure during an etching process can be avoided, making it easier to form a super-long and ultra-thin semiconductor nanowire structure.

### BRIEF DESCRIPTION OF THE DRAWINGS

FIG. 1 is a flowchart illustrating a conventional “top-down” method for making silicon nanowires.

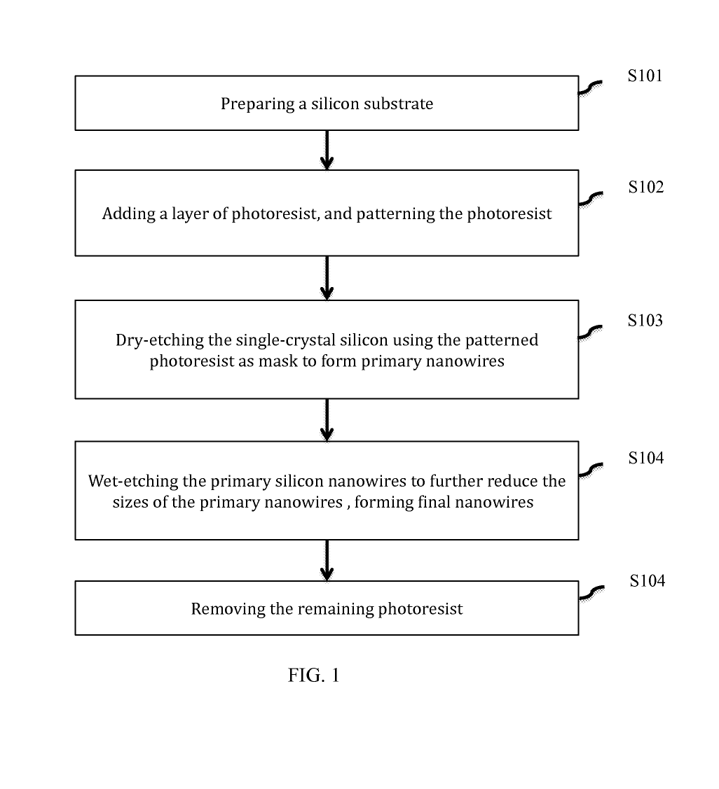

FIGS. 2A to 2E are structural diagrams of a silicon substrate corresponding to respective steps in the “top-down” method for making the silicon nanowires.

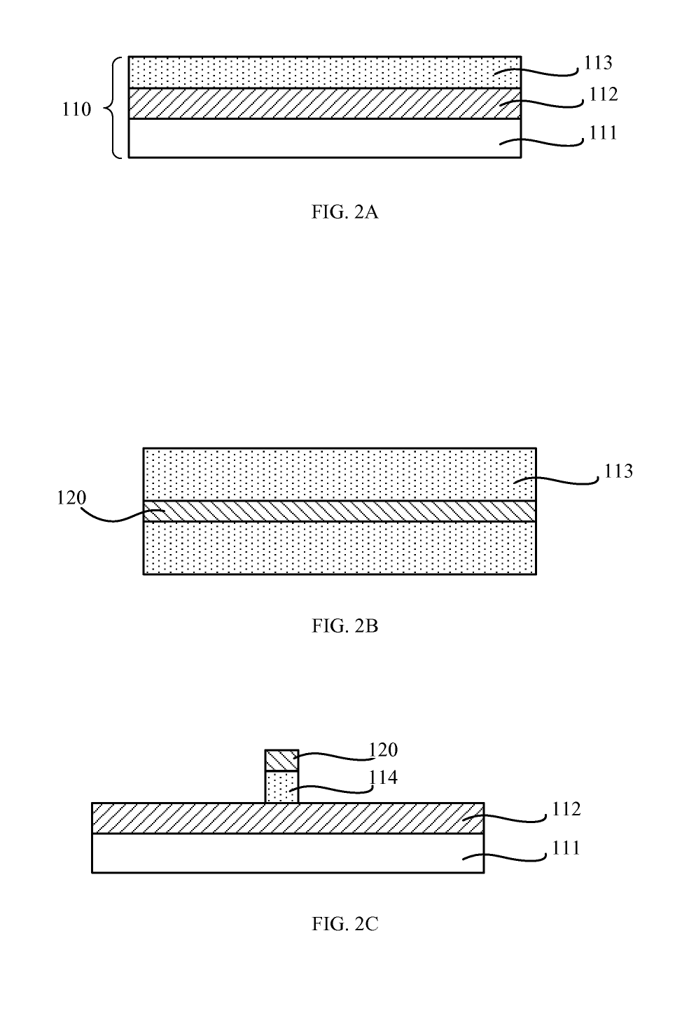

FIG. 3 is a block diagram illustrating a super-long semiconductor nanowire structure according to embodiments of the present invention.

FIG. 4 is a flowchart illustrating a method for making a super-long semiconductor nanowire structure according to an embodiment of the present invention.

FIGS. 5A to 5C are structural diagrams of a semiconductor substrate corresponding to respective steps in the method for making a super-long semiconductor nanowire structure according to the embodiment illustrated in FIG. 4.

FIG. 6 is a flowchart illustrating a method for making a super-long semiconductor nanowire structure according to an alternative embodiment of the present invention.

FIG. 7 is a flowchart illustrating a method for making a super-long semiconductor nanowire structure according to yet another alternative embodiment of the present invention.

### DESCRIPTION OF EMBODIMENTS

The super-long semiconductor nanowire structure and method of making according to embodiments of the present invention are explained in more detail with reference to the drawings. The advantages and characteristics of the present invention will be clearer after the following specification and claims. Note that the drawings all use simplified forms and inaccurate proportions and are used only to help in easily and clearly explaining the embodiments of the present invention.

A key idea of the present invention is to provide a super-long semiconductor nanowire structure. The super-long semiconductor nanowire structure is intermittently widened to prevent fractures in the super-long semiconductor nanowire structure. At the same time, the present invention further provides a method of making a super-long semiconductor nanowire structure. The method forms an intermittently widened super-long semiconductor nanowire structure using photolithography and etching. Because the super-long semiconductor nanowire structure is intermittently widened, fracturing of the super-long semiconductor nanowire structure during etching can be avoided, making it easier to form a super-long and ultra-thin semiconductor nanowire structure.

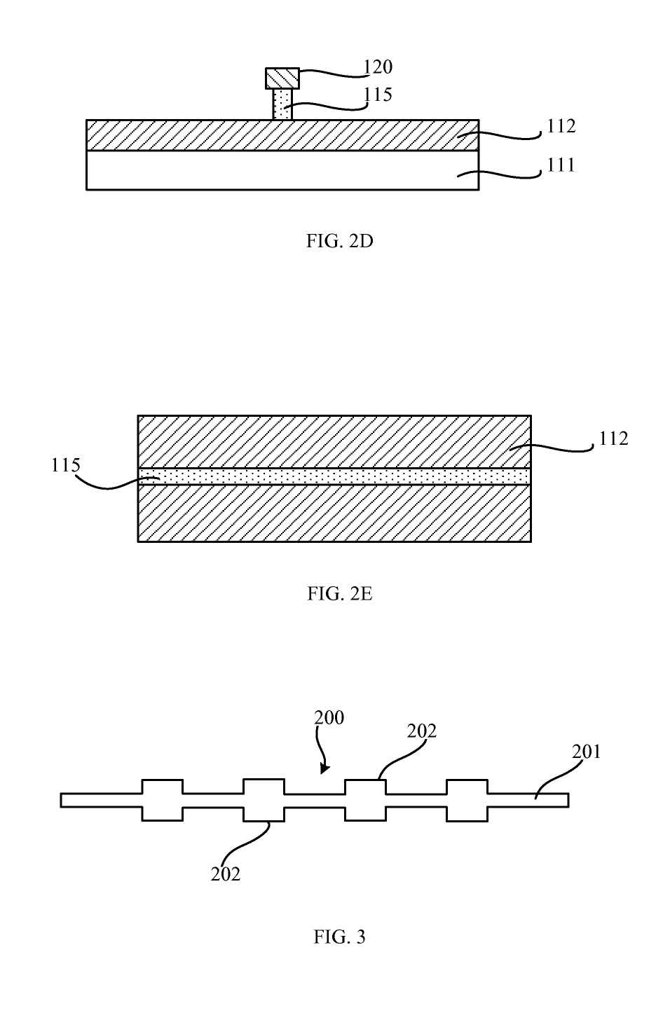

Reference is now made to FIG. 3, which is a block diagram illustrating a super-long semiconductor nanowire structure according to embodiments of the present invention. As shown in FIG. 3, the super-long semiconductor nanowire structure 200 provided by embodiments of the present invention comprises a super-long semiconductor nanowire 201 and flanges 202. The flanges 202 are symmetrically disposed on two sides of the semiconductor nanowire 201, thereby widening the super-long semiconductor nanowire 201, and the flanges 202 on a either side of the nanowire 201 are intermittently disposed with spaces therebetween. Because the super-long semiconductor nanowire structure 200 is intermittently widened, fracturing of the super-long semiconductor nanowire structure 200 can be avoided.

In a further embodiment, the flanges are about 2˜100 nm wide.

In a further embodiment, the super-long semiconductor nanowire 201 is about 0.5˜500 μm long.

In a further embodiment, the super-long semiconductor nanowire 201 is about 2˜200 nm wide.

In a further embodiment, the flanges 202 and the super-long semiconductor nanowire 201 are formed together as a one-piece structure.

In a further embodiment, the super-long semiconductor nanowire 201 is a super-long silicon nanowire or a super-long germanium nanowire, and the flanges 202 are respectively silicon flanges or germanium flanges.

A method of making a super-long semiconductor nanowire structure is explained in detail using the following examples.

### Example 1

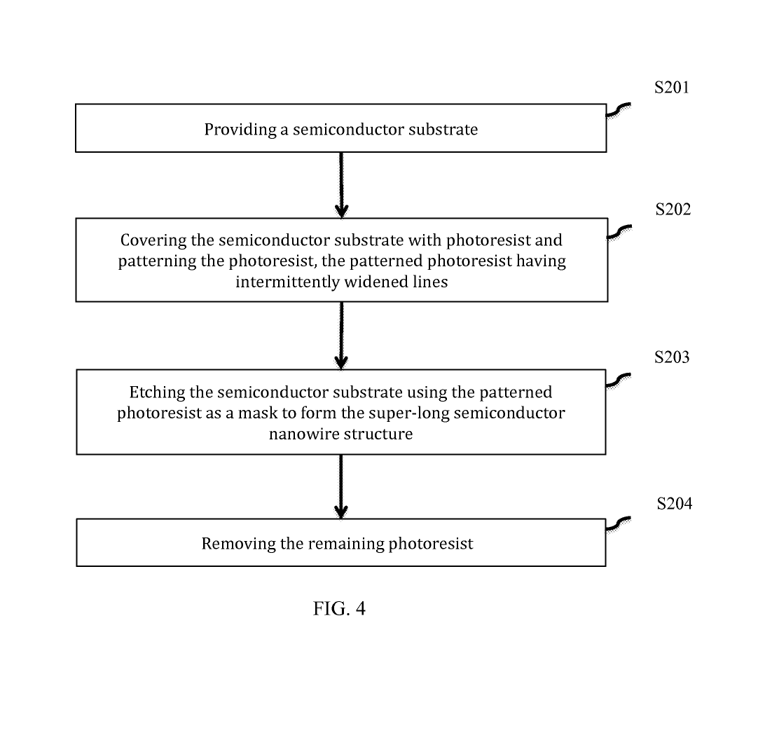

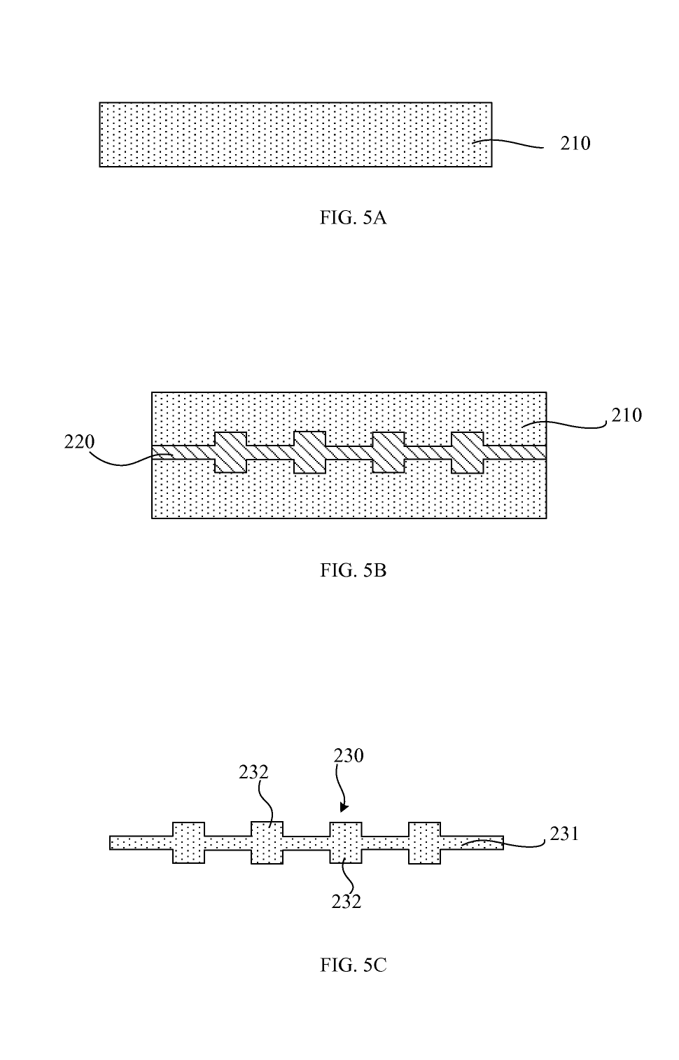

Reference is now made to FIG. 4, and FIGS. 5A to 5C, wherein FIG. 4 is a flowchart illustrating a method for making a super-long semiconductor nanowire structure according to an embodiment of the present invention, and FIGS. 5A to 5C are structural diagrams of a semiconductor substrate corresponding to respective steps in the method for making a super-long semiconductor nanowire structure according to the embodiment illustrated in FIG. 4. As shown in FIG. 4, and FIGS. 5A to 5C, the method for making a super-long semiconductor nanowire structure according to this embodiment comprises:
S201—providing a semiconductor substrate 201, as shown in FIG. 5A;
S202—covering the semiconductor substrate 210 with photoresist 220 and patterning the photoresist 220, the patterned photoresist 220 having an intermittently widened line shape, as shown in an overview of the patterned photoresist 220 in FIG. 5B;
S203—wet-etching the semiconductor substrate 210 using the patterned photoresist 220 as a mask to form the super-long semiconductor nanowire structure 230; and
S204—removing the remaining photoresist 220, as shown in FIG. 5C, which is an overview of the semiconductor substrate after the remaining photoresist is removed, wherein the super-long semiconductor nanowire structure 230 comprises a super-long semiconductor nanowire 231 and flanges 232, the flanges 232 being symmetrically disposed on two sides of the semiconductor nanowire 231, thereby widening the super-long semiconductor nanowire 231, the flanges 232 on either side of the nanowire 231 being intermittently disposed with spaces therebetween.

In a further embodiment, the photoresist is patterned using any of photolithography, nano-imprint lithography, electron-beam (e-beam) lithography, and X-ray lithography methods.

In a further embodiment, an etchant used during the wet etching is KOH or hydroxide four methyl amine, thereby the semiconductor substrate 210 can be anisotropically etched.

In a further embodiment, the flanges 232 are about 2˜100 nm wide.

In a further embodiment, the super-long semiconductor nanowire 231 is about 0.5˜500 μm long.

In a further embodiment, the super-long semiconductor nanowire 231 is about 2˜200 nm wide.

In a further embodiment, the flanges 232 and the super-long semiconductor nanowire 231 are formed together as a one-piece structure.

In a further embodiment, the semiconductor substrate 210 is single-crystal silicon or silicon on insulator, the super-long semiconductor nanowire 231 is a super-long silicon nanowire, and the flanges 232 are silicon flanges.

In a further embodiment, the semiconductor substrate 210 is single-crystal germanium or germanium on insulator, the super-long semiconductor nanowire 231 is a super-long germanium nanowire, and the flanges 232 are germanium flanges.

### Example 2

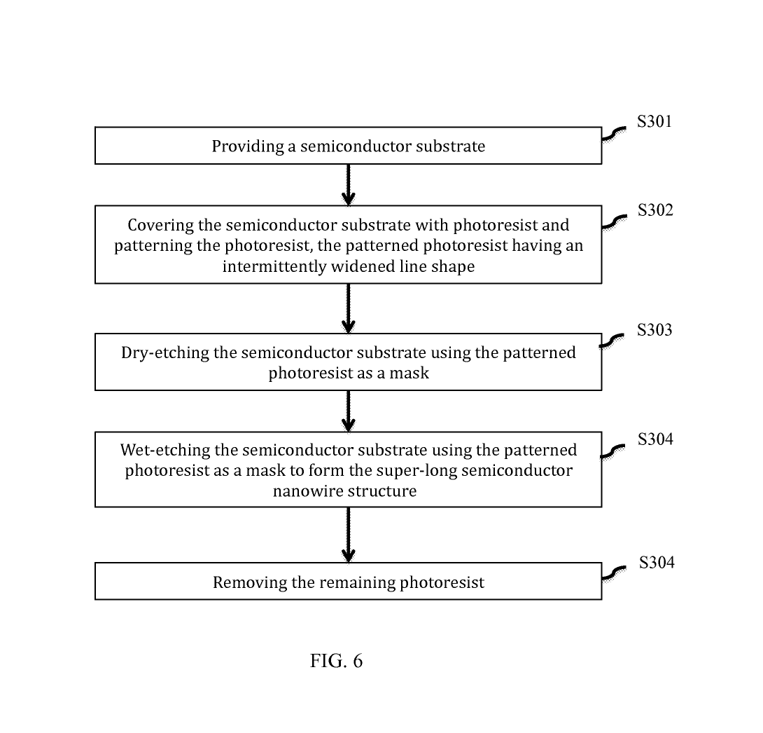

Reference is now made to FIG. 6, which is a flowchart illustrating a method for making a super-long semiconductor nanowire structure according to an alternative embodiment of the present invention. As shown in FIG. 6, the method for making a super-long semiconductor nanowire structure according to this embodiment comprises:
S301—providing a semiconductor substrate;
S302—covering the semiconductor substrate with photoresist and patterning the photoresist, the patterned photoresist having an intermittently widened line shape;
S303—dry-etching the semiconductor substrate using the patterned photoresist as a mask;
S304—wet-etching the semiconductor substrate using the patterned photoresist as a mask to form the super-long semiconductor nanowire structure; and
S305—removing the remaining photoresist.

Note that except the difference on how etching is performed on the semiconductor substrate, Example 2 is similar to Example 1. Thus, there is no need to repeat other aspects of the examples. In Example 2, a dry-etching step is added before wet-etching the semiconductor substrate because dry-etching has better directionality to form more vertical patterns. However, the patterns formed using the dry-etching step can still be oversized. So, wet etching is used after the dry etching step to further reduce the pattern sizes, so as to form super-long and ultra-thin semiconductor nanowire structures.

In a further embodiment, an etchant gas used during the wet etching includes at least one of CF₄, SiF₆, Cl₂, HBr, and HCl.

### Example 3

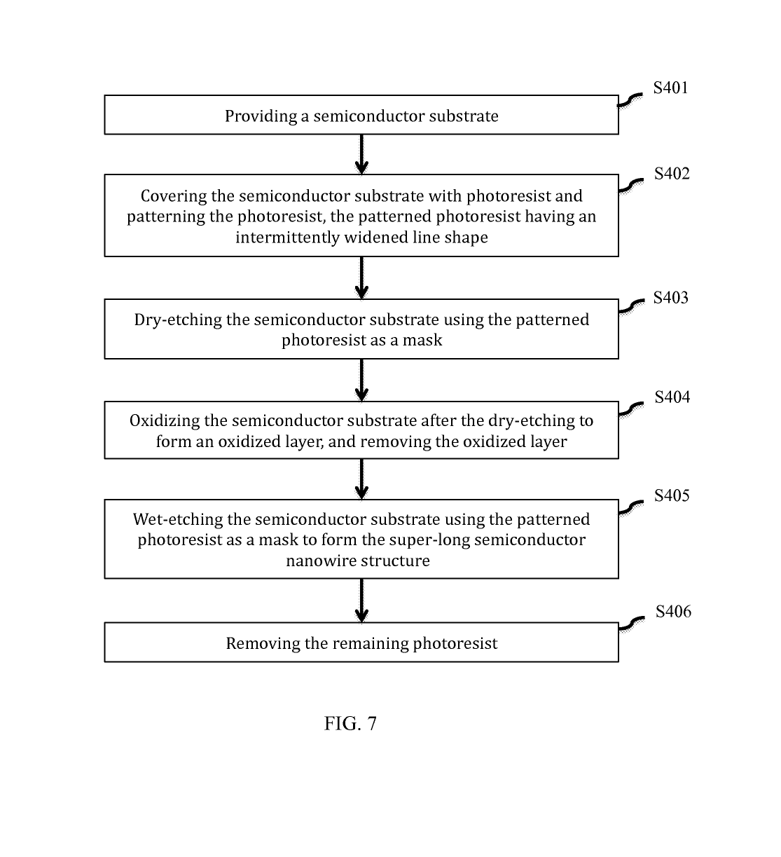

Reference is now made to FIG. 7, which is a flowchart illustrating a method for making a super-long semiconductor nanowire structure according to yet another alternative embodiment of the present invention. As shown in FIG. 7, the method for making a super-long semiconductor nanowire structure according to this embodiment comprises:
S401—providing a semiconductor substrate;
S402—covering the semiconductor substrate with photoresist and patterning the photoresist, the patterned photoresist having an intermittently widened line shape;
S403—dry-etching the semiconductor substrate using the patterned photoresist as a mask;
S404—oxidizing the semiconductor substrate after the dry-etching to form an oxidized layer, and removing the oxidized layer using, for example, HF;
S405—wet-etching the semiconductor substrate using the patterned photoresist as a mask to form the super-long semiconductor nanowire structure; and
S406—removing the remaining photoresist.

Note that except the difference on how etching is performed on the semiconductor substrate, Example 3 is similar to Example 2. Thus, there is no need to repeat other aspects of the examples. In Example 3, a semiconductor substrate oxidation step is added after dry-etching the semiconductor substrate and before wet-etching the semiconductor substrate. By oxidizing the semiconductor substrate, an oxidized layer is formed on two sides of a pattern formed using the dry etching. After removing the oxidized layer, the pattern formed by the dry etching would be narrower, making it easier to form ultra-thin and super-long semiconductor nanowire structure.

In summary, the present invention provides a super-long semiconductor nanowire structure. The super-long semiconductor nanowire structure is intermittently widened to prevent fractures in the super-long semiconductor nanowire structure. At the same time, the present invention further provides a method of making a super-long semiconductor nanowire structure. The method forms an intermittently widened super-long semiconductor nanowire structure using photolithography and etching. Because the super-long semiconductor nanowire structure is intermittently widened, fracturing of the super-long semiconductor nanowire structure during etching can be avoided, making it easier to form a super-long and ultra-thin semiconductor nanowire structure.

Obviously, those skilled in the art can make various changes and modification of the present invention without departing from the spirit and scope of the present invention. Thus, the present invention intends to include such changes and modifications if such changes and modifications are within the scope of the claims and their equivalents.

1. A super-long semiconductor nanowire structure, comprising: a super-long semiconductor nanowire and flanges, the flanges being symmetrically disposed on two sides of the super-long semiconductor nanowire, thereby intermittently widening the super-long semiconductor nanowire, wherein the flanges on either side of the super-long semiconductor nanowire are intermittently disposed with spaces therebetween.

2. The super-long semiconductor nanowire structure according to claim 1, wherein the flanges are about 2˜100 nm wide.

3. The super-long semiconductor nanowire structure according to claim 2, wherein the super-long semiconductor nanowire is about 0.5˜500 μm long.

4. The super-long semiconductor nanowire structure according to claim 3, wherein the super-long semiconductor nanowire is about 2˜200 nm wide.

5. The super-long semiconductor nanowire structure according to claim 1, wherein the flanges and the super-long semiconductor nanowire are formed together as a one-piece structure.

6. The super-long semiconductor nanowire structure according to claim 5, wherein the super-long semiconductor nanowire is a super-long silicon nanowire or a super-long germanium nanowire, and the flanges are respectively silicon flanges or germanium flanges.

7. A method for making a super-long semiconductor nanowire structure, the method comprising:
forming a patterned mask layer on the semiconductor substrate, the patterned photoresist layer having an intermittently widened line shape;
etching the semiconductor substrate using the patterned photoresist as a mask to form a super-long semiconductor nanowire structure; and
removing remaining mask layer.

8. The method of making a super-long semiconductor nanowire structure according to claim 7, wherein, the mask is made of photoresist, and wherein the photoresist is patterned using any of photolithography, nano-imprint lithography, electron-beam lithography, and X-ray lithography methods.

9. The method of making a super-long semiconductor nanowire structure according to claim 7, wherein the etching is wet etching or dry etching followed by wet etching.

10. The method of making a super-long semiconductor nanowire structure according to claim 9, wherein an etchant used during the wet etching is KOH or hydroxide four methyl amine.

11. The method of making a super-long semiconductor nanowire structure according to claim 9, wherein an etchant gas used during the dry etching includes at least one of CF₄, SiF₆, Cl₂, HBr, and HCl.

12. The method of making a super-long semiconductor nanowire structure according to claim 9, further comprising oxidizing the semiconductor substrate before the wet etching.

13. The method of making a super-long semiconductor nanowire structure according to claim 7, wherein the super-long semiconductor nanowire structure comprises a super-long semiconductor nanowire and flanges, and wherein the flanges are about 2˜100 nm wide.

14. The method of making a super-long semiconductor nanowire structure according to claim 13, wherein the super-long semiconductor nanowire structure comprises a super-long semiconductor nanowire and flanges, and wherein the super-long semiconductor nanowire is about 0.5˜500 μm long.

15. The method of making a super-long semiconductor nanowire structure according to claim 14, wherein the super-long semiconductor nanowire structure comprises a super-long semiconductor nanowire and flanges, and wherein the super-long semiconductor nanowire is about 2˜200 nm wide.

16. The method of making a super-long semiconductor nanowire structure according to claim 7, wherein the super-long semiconductor nanowire structure comprises a super-long semiconductor nanowire and flanges, and wherein the flanges and the super-long semiconductor nanowire are formed together as a one-piece structure.

17. The method of making a super-long semiconductor nanowire structure according to claim 16, wherein the semiconductor substrate is single-crystal silicon or silicon on insulator, the super-long semiconductor nanowire is a super-long silicon nanowire, and the flanges are silicon flanges.

18. The method of making a super-long semiconductor nanowire structure according to claim 16, wherein the semiconductor substrate is single-crystal germanium or germanium on insulator, the super-long semiconductor nanowire is a super-long germanium nanowire, and the flanges are germanium flanges.
